(19) United States
(12) Patent Application Publication
(10) Pub. No.: US 2025/0061257 A1
(43) Pub. Date: Feb. 20, 2025

(54) Techniques For Reconfiguring Lookup Tables Using Memory During User Mode

(71) Applicant: Altera Corporation, San Jose, CA (US)

(72) Inventors: Bee Yee Ng, Bayan Lepas (MY); Gaik Ming Chan, Butterworth (MY); Sergey Gribok, Santa Clara, CA (US); Scott Weber, Piedmont, CA (US)

(73) Assignee: Altera Corporation, San Jose, CA (US)

(21) Appl. No.: 18/936,210

(22) Filed: Nov. 4, 2024

(51) Int. Cl. G06F 30/343

(52) U.S. Cl. CPC G06F 30/343

(57) ABSTRACT

A system includes a hard network-on-chip (NOC) and lookup table random access memory (LUTRAM) circuits usable as logic gates in a user design for an integrated circuit and reprogrammable in a user mode of the integrated circuit through the hard NOC. The LUTRAM circuits are reconfigurable during the user mode of the integrated circuit by providing a bit through the hard NOC for storage in the one of the LUTRAM circuits.

### BACKGROUND

Configurable integrated circuits (ICs) can be configured by users to implement desired custom logic functions. In a typical scenario, a logic designer uses computer-aided design (CAD) tools to design a custom circuit design. When the design process is complete, the computer-aided design tools generate an image containing configuration data bits. The configuration data bits are then loaded into configuration memory elements that configure configurable logic circuits in the integrated circuit to perform the functions of the custom circuit design.

### BRIEF DESCRIPTION OF DRAWINGS

FIG. 1 is a diagram that illustrates an example of a lookup table random access memory (LUTRAM) circuit that includes memory circuits and a lookup table (LUT) circuit and is operable in a hybrid mode.

FIG. 2 is a diagram that illustrates an example of a set of 24 LUTRAMs that can be implemented in a configurable integrated circuit (IC) according to the techniques disclosed herein.

FIG. 3 is a diagram that illustrates an example of a technique for changing the LUTMASK setting stored in a LUTRAM in an integrated circuit (IC) during a hybrid mode using the techniques disclosed herein with respect to FIGS. 1-2.

FIG. 4A is a diagram that illustrates an example of a user application for a configurable integrated circuit (IC) that uses LUTRAMs.

FIG. 4B is a diagram that illustrates the user application of the configurable integrated circuit (IC) of FIG. 4A in which the hybrid modes of the LUTRAMs are used to change the multiplier constants implemented by the layers using the techniques disclosed herein with respect to FIGS. 1-3.

FIG. 5 is a diagram that illustrates an example of a configurable logic integrated circuit (IC).

FIG. 6A is a block diagram of a system that can be used to implement a circuit design to be programmed into a programmable logic device using design software.

FIG. 6B is a diagram that depicts an example of a programmable logic device that includes three fabric die and two base die that are connected to one another via microbumps.

FIG. 7 is a block diagram illustrating a computing system configured to implement one or more aspects of the embodiments disclosed herein.

FIG. 8 is a diagram of an adaptive logic module that can implement one or more aspects of the embodiments disclosed herein.

### DETAILED DESCRIPTION

Customers of configurable integrated circuits (ICs), such as field programmable gate arrays (FPGAs), often need to support on-the-fly reconfigurability in their logic-based circuit designs for the configurable ICs. On-the-fly logic reconfigurability is an important feature in multiple areas, such as reconfigurable switchboxes or reloadable weights in neural networks for machine learning applications. Customers of configurable ICs often do not want to use additional configurable logic and routing resources in configurable ICs to enable on-the-fly reconfigurability, because large circuit designs for configurable ICs are often congested, and using configurable routing resources for logic reconfigurability is often too expensive.

As FPGAs become larger, FPGAs are becoming harder to partially reconfigure, with multiple day compile times for large circuit designs. Some applications, such as machine learning, reuse similar circuit designs for FPGAs. For example, a typical machine learning inference design uses many dot products of the same or similar circuit design, but only changes the weights between iterations of the circuit design. For machine learning training, the structure of the neural network is identical, but the weights change more rapidly, and with larger precision. Implementing large arrays of high precision multipliers in an FPGA (e.g., for a neural network) is very expensive in terms of logic and routing resources. Using fixed coefficients is much more efficient, but requires potentially multi-day recompile times for an FPGA.

According to some examples disclosed herein, an integrated circuit (IC), such as an FPGA or other type of configurable IC, includes a hard network-on-chip (NOC) and a logic block, such as a lookup table random access memory (LUTRAM), that includes a memory circuit (e.g., random access memory or RAM) and reconfigurable logic gate circuits (e.g., lookup tables (LUTs) or Boolean logic gates). The IC enables on-the-fly logic reconfigurability by using the hard NOC to load and reload stored memory contents of the memory circuit in the logic block (e.g., a LUTRAM), while using the reconfigurable logic gate circuits in a circuit design for the IC during a user mode. Thus, the hard NOC provides data for storage in the memory circuit in the logic block, while the circuit design for the IC uses the reconfigurable logic gate circuits in the logic block in user mode. The reconfigurable logic gate circuits in the logic block can be reconfigured during the user mode of the IC by providing data through the hard NOC to the memory circuit in the logic block and storing the data in the memory circuit. The data stored in the memory circuit is then used to reconfigure the functionality of the reconfigurable logic gate circuits. This on-the-fly logic reconfigurability of the reconfigurable logic gate circuits in the IC may or may not use reconfigurable routing resources in the IC.

One or more specific examples are described below. In an effort to provide a concise description of these examples, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

Throughout the specification, and in the claims, the terms “connected” and “connection” mean a direct electrical connection between the circuits that are connected, without any intermediary devices. The terms “coupled” and “coupling” mean either a direct electrical connection between circuits or an indirect electrical connection through one or more passive or active intermediary devices that allows the transfer of information between circuits. The term “circuit” may mean one or more passive and/or active electrical components that are arranged to cooperate with one another to provide a desired function.

This disclosure discusses integrated circuit devices, including configurable (programmable) integrated circuits, such as field programmable gate arrays (FPGAs) and programmable logic devices. As discussed herein, an integrated circuit (IC) can include hard logic and/or soft logic. The circuits in an integrated circuit device (e.g., in a configurable IC) that are configurable by an end user are referred to as “soft logic.” “Hard logic” generally refers to circuits in an integrated circuit device that have substantially less configurable features than soft logic or no configurable features.

An MLAB (Memory Logic Array Block) is a distributed memory block in the core fabric region of some types of FPGAs. An MLAB can be configured to support lookup table (LUT) mode or a random access memory (RAM) mode. In previously known FPGA devices, there was no hardware support to allow users to switch between LUT mode and RAM mode in an MLAB on-the-fly during the user mode without reconfiguring or partially reconfiguring the FPGA devices. According to additional examples disclosed herein, a new hybrid mode for an MLAB or LUTRAM in an FPGA is provided that allows a user to switch between LUT mode and RAM mode, without performing any reconfiguration or partial reconfiguration (PR) of the FPGA. As a result, users of FPGAs can change fixed coefficients, weights, or kernels in their applications on-the-fly, without the need to reconfigure and recompile their circuit designs.

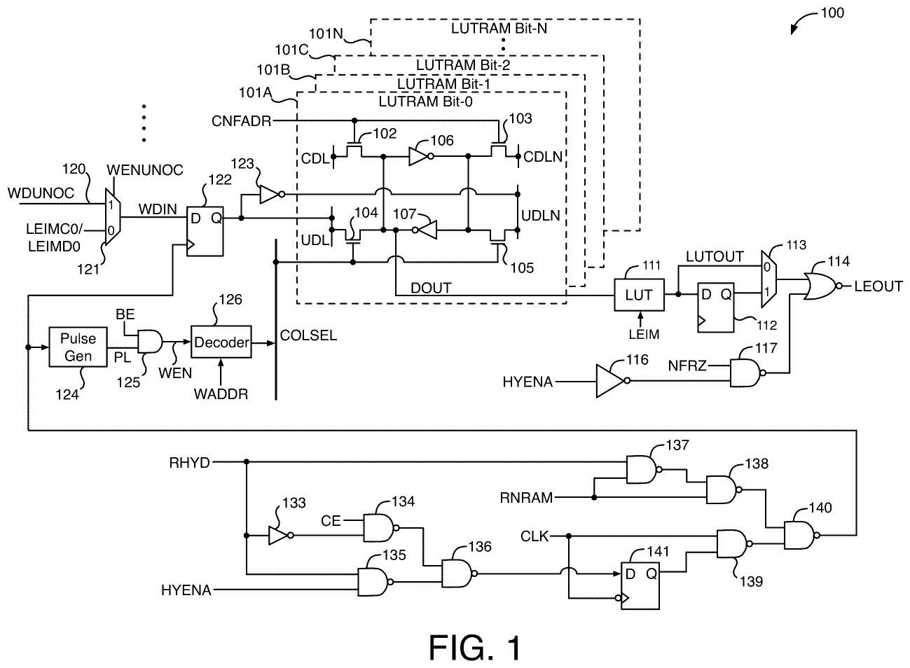

FIG. 1 is a diagram that illustrates an example of a lookup table random access memory (LUTRAM) circuit 100 that includes memory circuits 101 and a lookup table (LUT) circuit 111. The LUTRAM circuit 100 of Figure (FIG.) 1 includes an N number of random access memory (RAM) circuits 101A, 101B, 101C, . . . 101N (collectively referred to herein as memory circuits 101 or memory cells 101). Each of the memory circuits 101 includes two cross-coupled inverter circuits 106-107 and 4 n-channel field effect transistors (FETs) 102, 103, 104, and 105 that are coupled as shown in FIG. 1. FET 102 is an access transistor that is coupled to a configuration data line CDL. FET 103 is an access transistor that is coupled to an inverted configuration data line CDLN. FET 104 is an access transistor that is coupled to a user data line UDL. FET 105 is an access transistor that is coupled to an inverted user data line UDLN.

LUTRAM 100 also includes lookup table (LUT) circuit 111, register circuit 112 (i.e., a D flip-flop), multiplexer circuit 113, NOR logic gate circuit 114, inverter circuit 116, and NAND logic gate circuit 117. LUTRAM 100 further includes multiplexer circuit 121, register circuit 122 (i.e., a D flip-flop), inverter circuit 123, pulse generator circuit 124, AND logic gate circuit 125, and decoder circuit 126. LUTRAM circuit 100 further includes inverter circuit 133, 7 NAND logic gate circuits 134-140, and register circuit 141 (i.e., a D flip-flop).

LUTRAM 100 can be fabricated in any type of integrated circuit, such as a configurable IC (e.g., a field programmable gate array (FPGA) or programmable logic device (PLD)), a microprocessor IC, a graphics processing unit IC, a memory IC, an application specific IC, a transceiver IC, etc. In the examples described below, LUTRAM 100 is in a configurable IC, such as an FPGA or PLD.

The operation of the LUTRAM 100 is now described in detail. The LUTRAM 100 includes a hybrid mode (also referred to herein as LUT-switch-RAM mode). In the hybrid mode, a LUTMASK (lookup table mask) for configuring LUT circuit 111 can be overwritten through LUTRAM bit cell user data line (i.e., UDL and UDLN) write ports during a user mode of the configurable IC. A corresponding signal RHYD (e.g., generated from a new configuration RAM bit) is provided to the LUTRAM 100 to enable the hybrid mode. The RHYD signal is provided to inputs of NAND logic gate circuits 135 and 137 and inverter circuit 133. The signal HYENA can be toggled to cause the LUTRAM 100 to switch into and out of the hybrid mode. LUTRAM 100 also receives a signal RNRAM (e.g., generated from a configuration RAM bit) at inputs of the NAND logic gate circuits 137-138 that determines when the LUTRAM 100 functions in a random access memory (RAM) mode or in a lookup table (LUT) mode. Table 1 below summarizes the modes of the LUTRAM 100 that are caused by various combinations of the logic states of configuration RAM bits RNRAM and RHYD.

TABLE 1

| MLAB mode | RNRAM | RHYD |
|---|---|---|
| RAM mode | 0 | 0 |
| LUT mode | 1 | 0 |
| Hybrid mode | 1 | 1 |

During the hybrid mode (i.e., LUT-switch-RAM mode), a user can assert a hybrid mode clock enable (memory cell write enable) signal HYENA to alter the LUTMASK contents of the LUTRAM 100. Signal HYENA is provided to the input of inverter circuit 116 and to an input of NAND logic gate circuit 135. Signal HYENA is asserted to a logic high state (i.e., a logic 1) to initiate a write operation to one or more of the memory circuits 101 in LUTRAM 100 during hybrid mode.

An output signal LEOUT of LUTRAM circuit 100 can be tied-off to a static value (e.g., a logic 1 or 0), depending on the fabric routing default state, when the LUTMASK contents of memory circuits 101 are being overwritten in response to the HYENA signal being asserted to a logic 1.

A logic 1 in a signal CE while signal RHYD is a logic 0 or both of signals RHYD and HYENA being logic 1s causes NAND logic gate circuit 136 to generate a logic 1 at the D input of register circuit 141. Register circuit 141 stores the logic 1 state at its D input at its Q output in response to a falling edge in clock signal CLK. In response to the next rising edge in the clock signal CLK, NAND logic gate 139 generates a logic 0 at its output, which is provided to an input of NAND logic gate circuit 140. In response to the logic 0 at the output of NAND logic gate circuit 139, NAND logic gate circuit 140 generates a logic 1 at its output, which is provided to pulse generator circuit 124 and to a clock input of register circuit 122. The pulse generator circuit 124 generates a logic high (i.e., a logic 1) pulse in its output signal PL in response to the logic 1 at the output of NAND logic gate circuit 140. AND logic gate circuit 125 generates a logic 1 in its write enable output signal WEN in response to both the output signal PL of pulse generator circuit 124 and a signal BE (i.e., an MLAB lane-level access signal) concurrently being in logic 1 states. Table 2 below summarizes various combinations of logic states of signals that occur during the various modes of LUTRAM 100.

TABLE 2

| Mode | RNRAM | RHYD | HYENA | CE | BE | WEN |
|---|---|---|---|---|---|---|
| RAM mode | 0 | 0 | 0 | 0 | X | 0 |
| | 0 | 0 | 0 | 1 | 0 | 0 |
| | 0 | 0 | 0 | 1 | 1 | toggle |
| LUT mode | 1 | 0 | 0 | X | X | 0 |
| Hybrid mode | 1 | 1 | 0 | X | X | 0 |
| | 1 | 1 | 1 | X | 0 | 0 |
| | 1 | 1 | 1 | X | 1 | toggle |

Signal WEN can be enabled and toggled in hybrid mode, as shown in the last row of Table 2. Decoder circuit 126 receives signal WEN and write address signals WADDR. The write address signals WADDR indicate an address of the memory circuits 101 to write new data to during a write operation to alter the LUTMASK contents of the LUTRAM 100. The decoder circuit 126 decodes the address received in write address signals WADDR to generate column select signals COLSEL in response to sensing a logic 1 in the write enable signal WEN. One of the column select signals COLSEL is provided to each of the memory circuits 101A, 101B, 101C, . . . 101N. The column select signals COLSEL select one or more of the memory circuits 101A, 101B, 101C, . . . 101N to write data to during the write operation to alter the LUTMASK contents of the LUTRAM 100.

Memory circuit 101A is described below as being accessed for storing a new data bit during a write operation to alter the LUTMASK contents of LUTRAM 100 as an example that is not intended to be limiting. The description below can also apply to accessing any one or more of memory circuits 101 in LUTRAM 100 to alter the LUTMASK contents.

During configuration mode of the configurable IC, an address signal CNFADR is asserted to a logic 1 to turn on access FETs 102 and 103 to allow a configuration RAM (CRAM) bit to be provided to the memory circuit 101A through the configuration data line CDL and the inverted configuration data line CDLN and stored in the cross-coupled inverter circuits 106-107 in memory circuit 101A.

During the hybrid mode (i.e., LUT-switch-RAM mode), the signal WENUNOC is provided to a select input of multiplexer circuit 121. Also, a data signal WDUNOC is transmitted through a hard network-on-chip (NOC) 120 in the configurable IC to a first data input of the multiplexer circuit 121, or a data signal LEIMC0 or a data signal LEIMD0 is transmitted through configurable routing in the IC to a second data input of multiplexer circuit 121. Multiplexer circuit 121 provides the values of the data signal WDUNOC received from hard NOC 120 to its output as signal WDIN if signal WENUNOC is a logic 1. Multiplexer circuit 121 provides the values of the data signal LEIMC0/LEIMD0 to its output as signal WDIN if signal WENUNOC is a logic 0. Signal WENUNOC functions as an interrupt signal that enables data signal WDUNOC to be loaded from the hard NOC 120 to one or more of memory circuits 101.

Signal WDIN is provided to the D input of register circuit 122. Register circuit 122 stores the value of signal WDIN at its Q output in response to a rising edge in the output signal of AND logic gate circuit 140. The signal at the Q output of register circuit 122 is provided to the user data line UDL and to inverter circuit 123. Inverter circuit 123 provides the logically inverted value of the signal at the Q output of register circuit 122 to the inverted user data line UDLN. Thus, the values of the signals on the data lines UDL and UDLN reflect the value and inverted value, respectively, of the data signal WDUNOC or the data signal LEIMC0 or LEIMD0, depending on the logic state of signal WENUNOC.

In the example described below in which a data bit is written to memory circuit 101A during a write operation in the hybrid mode of the LUTRAM 100, decoder circuit 126 asserts one of the column select signals COLSEL to a logic 1 to turn on the access FETs 104 and 105 in memory circuit 101A. Decoder circuit 126 decodes the write address indicated by write address signals WADDR to generate the column select signals COLSEL in response to a logic 1 in write enable signal WEN. In response to FETs 104-105 in memory circuit 101A being on, the data bit indicated by the data signal at the Q output of register circuit 122 is provided through the user data line UDL and the inverted user data line UDLN and through FETs 104-105 to the inverter circuits 106-107 and stored in the inverter circuits 106-107 in memory circuit 101A during the write operation. The data bit that is stored in the inverter circuits 106-107 in memory circuit 101A during the write operation is indicated by the value of the data signal at the Q output of register circuit 122, which is provided from data signal WDUNOC or LEIMC0, or LEIMD0. Using this technique, new data can be written to any one or more of the memory circuits 101 in LUTRAM 100 during a write operation to alter the LUTMASK contents of LUTRAM 100 (e.g., using additional circuits 121-123 in LUTRAM 100 for each memory circuit 101).

The value of the data bit stored in the inverter circuits 106-107 in memory circuit 101A is provided to an input of LUT circuit 111 as signal DOUT. The values of the data bits stored in the other memory circuits 101 in LUTRAM 100 (i.e., memory circuits 101B, 101C, . . . 101N) are provided to additional inputs of the LUT circuit 111. The LUT circuit 111 performs a Boolean logic function based on user LUT input signals LEIM using the data bits stored in each of the memory circuits 101 in LUTRAM 100 to generate the value of its output signal LUTOUT during the hybrid mode. If LUT 111 is implemented as one or more multiplexers, then the data bits stored in the memory circuits 101 are provided to the data inputs of the multiplexer(s), and the LEIM signals are provided to the select inputs of the multiplexer(s). In this example, the multiplexer(s) in LUT 111 provide the value of one of the data bits from one of the memory circuits 101 as signal LUTOUT based on the values of signals LEIM.

The output signal LUTOUT of LUT circuit 111 is provided to a data input of multiplexer circuit 113 and to the D input of register circuit 112. Register circuit 112 stores the value of the signal LUTOUT at its Q output in response to a clock signal (not shown). Multiplexer circuit 113 is configurable to provide the value of the signal LUTOUT or the value of the signal at the Q output of register circuit 112 to a first input of NOR logic gate circuit 114.

In response to signal HYENA being a logic 1, inverter circuit 116 generates a logic 0 in its output signal. In response to either of signal NFRZ or the output signal of inverter circuit 116 being a logic 0, NAND logic gate circuit 117 generates a logic 1 in its output signal at the second input of NOR logic gate circuit 114. NOR logic gate circuit 114 generates the value of its output signal LEOUT by performing a NOR Boolean logic function on the logic values of the signals at its first and second inputs.

According to a first implementation of LUTRAM 100 in the hybrid mode, the select signal WENUNOC is set to a logic 0 to cause the multiplexer circuit 121 to provide the value of the data signal LEIMC0 or LEIMD0 to its output as signal WDIN. The LUTRAM 100 can have a different multiplexer circuit 121, register circuit 122, and inverter circuit 123 coupled to each group of the memory circuits 101. The number of memory circuits 101 in each of the groups can depend on a write address deep mode. For example, in a 32×2 write address deep mode, the COLSEL signals have 32 signals, and multiplexers 121 generate 2 WDIN signals. In a 16×4 write address deep mode, the COLSEL signals have 16 signals, and multiplexers 121 generate 4 WDIN signals.

In the first implementation, a first one of the multiplexer circuits 121 is configured to receive and provide the value of data signal LEIMC0 to a first one of the memory circuits 101, and a second one of the multiplexer circuits 121 is configured to receive and provide the value of data signal LEIMD0 to a second one of the memory circuits 101. In the first implementation, the data signals LEIMC0 and LEIMD0 indicate data bits that are written to two of the memory circuits 101 during a write operation to change the LUTMASK of the LUT circuit 111. LUTRAM 100 also receives additional input signals LEIMA, LEIMB, LEIMC1, LEIMD1, LEIME, and LEIMF that correspond to LUT input signals LEIM in FIG. 1. LUTRAM 100 also receives 5 write address signals and 2 BE signals via inputs LEIM_LRAM<6:0>. Examples of how the input signals to the LUTRAM 100 are used in RAM mode, LUT mode, and hybrid mode in the first implementation are shown in Table 3 below.

TABLE 3

| | RAM | LUT | Hybrid |
|---|---|---|---|
| User inputs | mode | mode | mode |
| LEIMA | RADDR<0> | LUT input | LUT input |
| LEIMB | RADDR<1> | LUT input | LUT input |
| LEIMC0 | WDATAIN<0> | LUT input | WDATAIN<0> |
| LEIMD0 | WDATAIN<1> | LUT input | WDATAIN<1> |
| LEIMC1 | RADDR<2> | LUT input | LUT input |
| LEIMD1 | RADDR<3> | LUT input | LUT input |
| LEIME | RADDR<4> | LUT input | LUT input |
| LEIMF | RADDR<4> | LUT input | LUT input |
| LEIM_LRAM<6:0> | WADDR<4:0>, | Not | WADDR<4:0>, |
| | BE<1:0> | applicable | BE<1:0> |

In Table 3, RADDR<4:0> indicate read address signals during RAM mode, WDATAIN<1:0> indicate write data bits during write operations to memory circuits 101 in RAM and hybrid modes, WADDR<4:0> indicate write address signals during the write operations to memory circuits 101 in RAM and hybrid modes, BE<1:0> indicate the BE signals during RAM and hybrid modes, and the LUT inputs indicate select input signals LEIM to the LUT circuit 111 during LUT and hybrid modes.

In the first implementation, each MLAB (e.g., 24 LUTRAMs 100) uses M-bit LEIMC0/LEIMD0 data signals indicating write data bits to write to LUTRAMs 100 from a core fabric region of the configurable IC, where M can be any number of bits (e.g., 24-bits). The M-bit LEIMC0/LEIMD0 data signals can be transmitted from the core fabric region to LUTRAM 100 through configurable routing channels in the IC. Also, in the first implementation of LUTRAM 100 in the hybrid mode, input signals LEIMA, LEIMB, LEIMC1, LEIMD1, LEIME, and LEIMF are the 6 LUT input signals shown as signals LEIM in FIG. 1. Thus, in the first implementation, LUTRAM 100 may support less than the full MLAB LUT functions. For example, in the hybrid mode shown in Table 3, LUT circuit 111 may only support a 6-input lookup table function or part of a fractured lookup table mode.

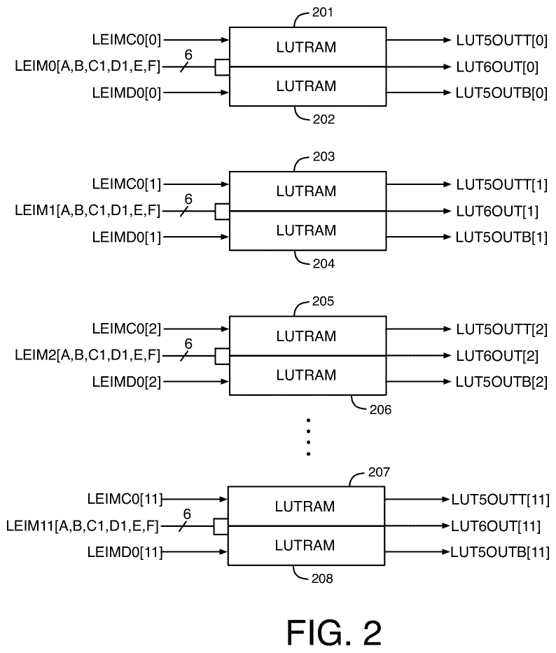

FIG. 2 is a diagram that illustrates an example of a set of 24 LUTRAMs in an MLAB that can be implemented in a configurable integrated circuit (IC) according to the techniques disclosed herein. FIG. 2 shows 8 LUTRAMs 201, 202, 203, 204, 205, 206, 207, and 208 of the 24 LUTRAMs in the set. The 24 LUTRAMs of FIG. 2 are arranged in 12 pairs. Each pair of the LUTRAMs in the set receives at least 8 input signals and generates 3 output signals. Each of the 24 LUTRAMs of FIG. 2 includes an instance of the LUTRAM 100 of FIG. 1. Thus, the MLAB of FIG. 2 has 24 LUTRAMs 100.

As an example, LUTRAM 201 receives input signals LEIMC0[0] and LEIM0[A, B, C1, D1, E, F], LUTRAM 202 receives input signals LEIMD0[0] and LEIM0[A, B, C1, D1, E, F], and LUTRAMs 201-202 generate output signals LUT50UTT[0], LUT60UT[0], and LUT50UTB[0], where LEIM0[A, B, C1, D1, E, F] represent the 6 LUT input signals in Table 3. As an example that is not intended to be limiting, each of the 24 LUTRAMs of FIG. 2 can be a 32×1 LUTRAM.

The LUTRAMs of FIG. 2 can, for example, be configured according to the first implementation described above. In the first implementation of the LUTRAMs of FIG. 2 during hybrid mode, input signals LEIMC0<11:0> and LEIMD0<11:0> are used for transmitting the write data bits WDATAIN<1:0> for storage in the memory circuits 101 in the respective LUTRAMs, the LEIM<11:0>[A,B,C1,D1,E,F] input signals are provided to the select inputs of the lookup table (LUT) circuits 111 in the respective LUTRAMs, and the output signals of the respective LUTRAMs are LUT50UTT<11:0>, LUT50UTB<11:0> and LUT60UT<11:0>. Each MLAB containing 24 LUTRAMs uses 24-bit LEIMC0/LEIMD0 input signals to write to the LUTRAM memory circuits 101 from the core fabric region of the configurable IC, which may increase routing congestion and logic resource overhead in the IC.

According to a second implementation of LUTRAM 100 in the hybrid mode, the select signal WENUNOC is set to a logic 1 to cause the multiplexer circuit 121 to provide the value of the data signal WDUNOC from hard NOC 120 to the output of multiplexer circuit 121 as signal WDIN. LUTRAM 100 can have an additional multiplexer circuit 121, an additional register circuit 122, and an additional inverter circuit 123 to provide a data bit to each of the memory circuits 101 in the hybrid mode.

In the second implementation, one or more of the multiplexer circuits 121 can be configured to receive and provide one or more data bits indicated by one or more data signals WDUNOC from the hard NOC 120 to corresponding ones of the memory circuits 101 through the corresponding register circuits 122 and inverter circuits 123. In the second implementation, the one or more data signals on the hard NOC 120 indicate one or more data bits that are written to one or more of the memory circuits 101 during write operations to change the LUTMASK of the LUT circuit 111 in hybrid mode.

If the hard NOC 120 has a high data bandwidth (e.g., 1-10 terabytes per second), using the hard NOC 120 to transmit the write data bits to the LUTRAM 100 in the hybrid mode can substantially decrease the time to change some or all of the data contents stored in the memory circuits 101. Using the hard NOC 120 to transmit the write data bits to the LUTRAM 100 may, for example, be 8-16 times faster than using partial reconfiguration of the configurable IC to change the data contents stored in the memory circuits 101 of the LUTRAM 100.

Examples of how the input signals to LUTRAM 100 are used in RAM mode, LUT mode, and hybrid mode in the second implementation are shown in Table 4 below. In Table 4, RADDR<4:0> indicate read address signals during RAM mode, WDATAIN<1:0> indicate write data bits during write operations to memory circuits 101 in RAM and hybrid modes, WADDR<4:0> indicate write address signals during the write operations to memory circuits 101 in RAM and hybrid modes, BE<1:0> indicate the BE signals during RAM and hybrid modes, and the LUT inputs indicate select input signals LEIM to the LUT circuit 111 during LUT and hybrid modes. In the second implementation, LUTRAM 100 uses two of the data signals WDUNOC<1:0> on the hard NOC 120 to indicate write data bits WDATAIN<0:1> to be written to the memory circuits 101 in the LUTRAM 100 in the hybrid mode, as shown in Table 4.

TABLE 4

| | RAM | LUT | Hybrid |
|---|---|---|---|
| User inputs | mode | mode | mode |
| LEIMA | RADDR<0> | LUT input | LUT input |
| LEIMB | RADDR<1> | LUT input | LUT input |
| LEIMC0 | WDATAIN<0> | LUT input | LUT input |
| LEIMD0 | WDATAIN<1> | LUT input | LUT input |
| LEIMC1 | RADDR<2> | LUT input | LUT input |
| LEIMD1 | RADDR<3> | LUT input | LUT input |
| LEIME | RADDR<4> | LUT input | LUT input |
| LEIMF | RADDR<4> | LUT input | LUT input |
| WDUNOC<0> | Not | Not | WDATAIN<0> |
| | applicable | applicable | |
| WDUNOC<1> | Not | Not | WDATAIN<1> |
| | applicable | applicable | |
| LEIM_LRAM<6:0> | WADDR<4:0>, | Not | WADDR<4:0>, |
| | BE<1:0> | applicable | BE<1:0> |

In the second implementation, LUTRAM 100 uses M-bit LEIMC0/LEIMD0 signals as LUT input signals to the LUT circuits 111 in hybrid and LUT modes, as shown in Table 4. Thus, in the second implementation of the LUTRAM 100 in the LUT and hybrid modes, the 8 input signals LEIMA, LEIMB, LEIMC0, LEIMD0, LEIMC1, LEIMD1, LEIME, and LEIMF are the 8 LUT input select signals, which are shown as signals LEIM in FIG. 1. Thus, in the second implementation, LUTRAM 100 can support the full MLAB LUT functions, and the LUT circuit 111 can support an 8-input lookup table function in the hybrid mode and all of the fractured lookup table mode functions in hybrid mode in the example shown in Table 4.

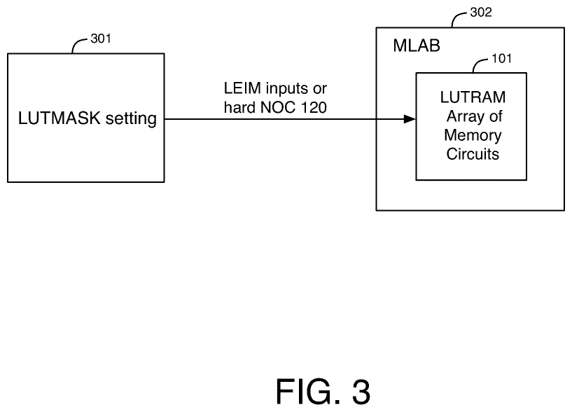

FIG. 3 is a diagram that illustrates an example of a technique for changing the LUTMASK setting stored in a LUTRAM 100 in an integrated circuit (IC) during the hybrid mode using the techniques disclosed herein with respect to FIGS. 1-2. In a conventional FPGA, users have to recompile the full FPGA IC to change the LUTMASK settings (e.g., coefficients of constant multipliers). According to the example of FIG. 3, a user of a configurable IC can change the LUTMASK setting 301 of a LUTRAM 100 using the techniques disclosed herein with respect to FIGS. 1-2 during the hybrid mode, without the need to recompile the circuit design for the IC.

A new LUTMASK setting 301 can be obtained from a software compilation of a circuit design for a configurable IC (e.g., using a new constant multipliers design for a machine learning application). The LUTMASK setting 301 can be transmitted through the LEIM inputs (e.g., according to the first implementation described above) or through the hard NOC 120 (e.g., according to the second implementation described above) to the LUTRAM array of memory circuits 101 (e.g., in an MLAB 302).

Many artificial intelligence (AI) applications for configurable ICs use low-precision floating-point arithmetic in configurable logic circuits, such as LUTRAMs. As an example, a convolution neural network (CNN) is able to fit four 6-bit multipliers in an MLAB containing 24 LUTRAMs as shown in FIG. 2. A user that implements a CNN in 24 LUTRAMs 100 with low-precision constant multipliers does not need to recompile the circuit design for the IC if the constants of the multipliers change. Instead of recompiling and reconfiguring the circuit design for the IC and/or the LUTRAMs, the multiplier constants in the LUTRAMs can be modified using the hybrid mode as disclosed herein with respect to FIGS. 1-3. The hybrid mode of the LUTRAMs 100 allow larger models to exist on a smaller configurable IC device by allowing the multiplier constants to change over time to allow reuse of the overlay.

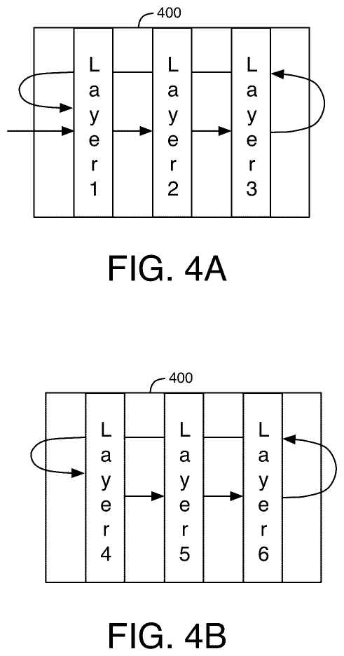

FIG. 4A is a diagram that illustrates an example of a user application for a configurable integrated circuit (IC) 400 that uses LUTRAMs 100. In FIG. 4A, the configurable IC 400 includes 3 layers (i.e., layer1, layer2, and layer3) of a circuit design that are each implemented by several LUTRAMs 100. These 3 layers can, for example, correspond to an overlay of multiplier constants or coefficients in an AI application, such as a neural network. The arrows in FIG. 4A illustrate the data bits loaded into the LUTRAMs to implement multiplier constants for the layers layer1-layer3.

FIG. 4B is a diagram that illustrates the user application of the configurable integrated circuit (IC) 400 in which the hybrid modes of the LUTRAMs 100 are used to change the multiplier constants implemented by the layers using the techniques disclosed herein with respect to FIGS. 1-3. In FIG. 4B, the configurable IC 400 includes 3 additional layers (i.e., layer4, layer5, and layer6) of the circuit design that are each implemented by the LUTRAMs 100. These 3 additional layers can, for example, correspond to a new overlay of different multiplier constants or coefficients for the AI application used in FIG. 4A. The arrows in FIG. 4B illustrate the modifications of the LUTMASK for the LUTRAMs to change the multiplier constants from the layers layer1-layer3 to the layers layer4-layer6.

The hybrid mode for LUTRAM 100 provides several advantages in a configurable IC. For example, the hybrid mode for LUTRAM 100 allow users to change fixed coefficients, weights, or kernels in applications for configurable ICs on-the-fly, without the need to reconfigure and recompile the circuit designs that implement these applications. In addition, the hybrid mode for LUTRAM 100 can enable breakthrough ease-of-use (i.e., no recompiling necessary) and can allow a circuit design for a configurable IC to be reused with identical performance and area. The arithmetic weights, kernels, etc. in a circuit design can be altered on-the-fly using the hybrid mode, as disclosed herein with respect to FIGS. 1-4. Also, a minimum amount of hardware circuitry overhead may be needed to support the hybrid mode for the LUTRAM 100.

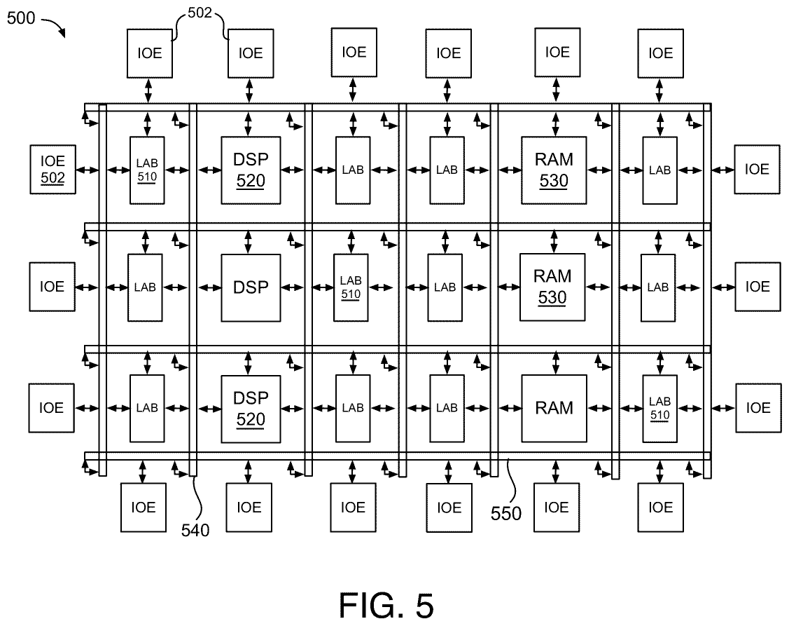

FIG. 5 illustrates an example of a configurable integrated circuit (IC) 500 that can include, for example, the circuitry and/or applications disclosed herein with respect to any, some, or all of FIGS. 1, 2, 3, 4A, and/or 4B. As shown in FIG. 5, the configurable integrated circuit (IC) 500 includes a two-dimensional array of configurable functional circuit blocks, including configurable logic array blocks (LABs) 510 and other functional circuit blocks, such as random access memory (RAM) blocks 530 and digital signal processing (DSP) blocks 520. Functional blocks such as LABs 510 can include smaller programmable logic circuits (e.g., logic elements, logic blocks, or adaptive logic modules) that receive input signals and perform custom functions on the input signals to produce output signals. The configurable IC 500 shown in FIG. 5 can, for example, include LUTRAMs 100, as disclosed herein with respect to FIG. 1.

In addition, configurable IC 500 can have input/output elements (IOEs) 502 for driving signals off of configurable IC 500 and for receiving signals from other devices. Input/output elements 502 can include parallel input/output circuitry, serial data transceiver circuitry, differential receiver and transmitter circuitry, or other circuitry used to connect one integrated circuit to another integrated circuit. As shown, input/output elements 502 can be located around the periphery of the chip. If desired, the configurable IC 500 can have input/output elements 502 arranged in different ways. For example, input/output elements 502 can form one or more columns, rows, or islands of input/output elements that may be located anywhere on the configurable IC 500.

The configurable IC 500 can also include programmable interconnect circuitry in the form of vertical routing channels 540 (i.e., interconnects formed along a vertical axis of configurable IC 500) and horizontal routing channels 550 (i.e., interconnects formed along a horizontal axis of configurable IC 500), each routing channel including at least one conductor to route at least one signal.

Note that other routing topologies, besides the topology of the interconnect circuitry depicted in FIG. 5, may be used. For example, the routing topology can include wires that travel diagonally or that travel horizontally and vertically along different parts of their extent as well as wires that are perpendicular to the device plane in the case of three dimensional integrated circuits. The driver of a wire can be located at a different point than one end of a wire.

Furthermore, it should be understood that embodiments disclosed herein with respect to FIGS. 1, 2, 3, 4A, and 4B can be implemented in any integrated circuit or electronic system. If desired, the functional blocks of such an integrated circuit can be arranged in more levels or layers in which multiple functional blocks are interconnected to form still larger blocks. Other device arrangements can use functional blocks that are not arranged in rows and columns.

Configurable IC 500 can contain programmable memory elements. Memory elements can be loaded with configuration data using input/output elements (IOEs) 502. Once loaded, the memory elements each provide a corresponding static control signal that controls the operation of an associated configurable functional block (e.g., LABs 510, DSP blocks 520, RAM blocks 530, or input/output elements 502).

In a typical scenario, the outputs of the loaded memory elements are applied to the gates of metal-oxide-semiconductor field-effect transistors (MOSFETs) in a functional block to turn certain transistors on or off and thereby configure the logic in the functional block including the routing paths. Programmable logic circuit elements that can be controlled in this way include multiplexers (e.g., multiplexers used for forming routing paths in interconnect circuits), lookup tables, logic arrays, AND, OR, XOR, NAND, and NOR logic gates, pass gates, etc.

The programmable memory elements can be organized in a configuration memory array having rows and columns. A data register that spans across all columns and an address register that spans across all rows can receive configuration data. The configuration data can be shifted onto the data register. When the appropriate address register is asserted, the data register writes the configuration data to the configuration memory bits of the row that was designated by the address register.

In certain embodiments, configurable IC 500 can include configuration memory that is organized in sectors, whereby a sector can include the configuration RAM bits that specify the functions and/or interconnections of the subcomponents and wires in or crossing that sector. Each sector can include separate data and address registers.

The configurable IC of FIG. 5 is merely one example of an IC that can be used with embodiments disclosed herein. The embodiments disclosed herein can be used with any suitable integrated circuit or system. For example, the embodiments disclosed herein can be used with numerous types of devices such as processor integrated circuits, central processing units, memory integrated circuits, graphics processing unit integrated circuits, application specific standard products (ASSPs), application specific integrated circuits (ASICs), and programmable logic integrated circuits. Examples of programmable logic integrated circuits include programmable arrays logic (PALs), programmable logic arrays (PLAs), field programmable logic arrays (FPLAs), electrically programmable logic devices (EPLDs), electrically erasable programmable logic devices (EEPLDs), logic cell arrays (LCAs), complex programmable logic devices (CPLDs), and field programmable gate arrays (FPGAs), just to name a few.

The integrated circuits disclosed in one or more embodiments herein can be part of a data processing system that includes one or more of the following components: a processor; memory; input/output circuitry; and peripheral devices. The data processing system can be used in a wide variety of applications, such as computer networking, data networking, instrumentation, video processing, digital signal processing, or any suitable other application. The integrated circuits can be used to perform a variety of different logic functions.

In general, software and data for performing any of the functions disclosed herein can be stored in non-transitory computer readable storage media. Non-transitory computer readable storage media is tangible computer readable storage media that stores data and software for access at a later time, as opposed to media that only transmits propagating electrical signals (e.g., wires). The software code may sometimes be referred to as software, data, program instructions, instructions, or code. The non-transitory computer readable storage media can, for example, include computer memory chips, non-volatile memory such as non-volatile random-access memory (NVRAM), one or more hard drives (e.g., magnetic drives or solid state drives), one or more removable flash drives or other removable media, compact discs (CDs), digital versatile discs (DVDs), Blu-ray discs (BDs), other optical media, and floppy diskettes, tapes, or any other suitable memory or storage device(s).

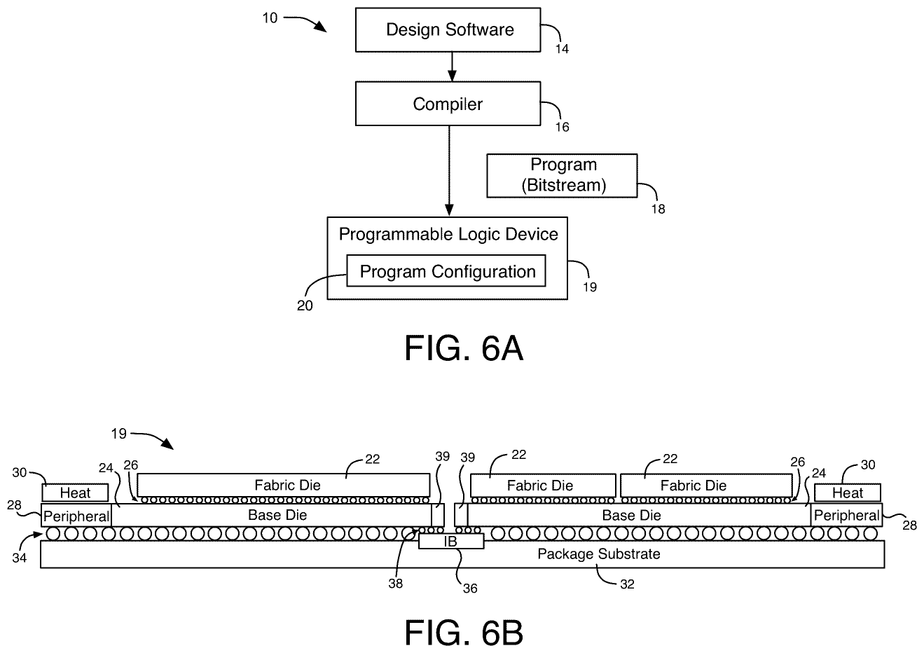

FIG. 6A illustrates a block diagram of a system 10 that can be used to implement a circuit design to be programmed into a programmable logic device 19 using design software. A designer can implement circuit design functionality on an integrated circuit, such as a reconfigurable programmable logic device 19 (e.g., a field programmable gate array (FPGA)). The designer can implement the circuit design to be programmed onto the programmable logic device 19 using design software 14. The design software 14 can use a compiler 16 to generate a low-level circuit-design program (bitstream) 18, sometimes known as a program object file and/or configuration program, that programs the programmable logic device 19. Thus, the compiler 16 can provide machine-readable instructions representative of the circuit design to the programmable logic device 19. For example, the programmable logic device 19 can receive one or more programs (bitstreams) 18 that describe the hardware implementations that should be stored in the programmable logic device 19. A program (bitstream) 18 can be programmed into the programmable logic device 19 as a configuration program 20. The configuration program 20 can, in some cases, represent an accelerator function to perform for machine learning, video processing, voice recognition, image recognition, or other highly specialized task.

In some implementations, a programmable logic device can be any integrated circuit device that includes a programmable logic device with two separate integrated circuit die where at least some of the programmable logic fabric is separated from at least some of the fabric support circuitry that operates the programmable logic fabric. One example of such a programmable logic device is shown in FIG. 6B, but many others can be used, and it should be understood that this disclosure is intended to encompass any suitable programmable logic device where programmable logic fabric and fabric support circuitry are at least partially separated on different integrated circuit die.

FIG. 6B is a diagram that depicts an example of the programmable logic device 19 that includes three fabric die 22 and two base die 24 that are connected to one another via microbumps 26. In the example of FIG. 6B, at least some of the programmable logic fabric of the programmable logic device 19 is in the three fabric die 22, and at least some of the fabric support circuitry that operates the programmable logic fabric is in the two base die 24. For example, some of the circuitry of configurable IC 500 shown in FIG. 5 (e.g., LABs 510, DSP 520, and RAM 530) can be located in the fabric die 22 and some of the circuitry of IC 500 (e.g., input/output elements 502) can be located in the base die 24.

Although the fabric die 22 and base die 24 appear in a one-to-one relationship or a two-to-one relationship in FIG. 6B, other relationships can be used. For example, a single base die 24 can attach to several fabric die 22, or several base die 24 can attach to a single fabric die 22, or several base die 24 can attach to several fabric die 22 (e.g., in an interleaved pattern). Peripheral circuitry 28 can be attached to, embedded within, and/or disposed on top of the base die 24, and heat spreaders 30 can be used to reduce an accumulation of heat on the programmable logic device 19. The heat spreaders 30 can appear above, as pictured, and/or below the package (e.g., as a double-sided heat sink). The base die 24 can attach to a package substrate 32 via conductive bumps 34. In the example of FIG. 6B, two pairs of fabric die 22 and base die 24 are shown communicatively connected to one another via an interconnect bridge 36 (e.g., an embedded multi-die interconnect bridge (EMIB)) and microbumps 38 at bridge interfaces 39 in base die 24.

In combination, the fabric die 22 and the base die 24 can operate in combination as a programmable logic device 19 such as a field programmable gate array (FPGA). It should be understood that an FPGA can, for example, represent the type of circuitry, and/or a logical arrangement, of a programmable logic device when both the fabric die 22 and the base die 24 operate in combination. Moreover, an FPGA is discussed herein for the purposes of this example, though it should be understood that any suitable type of programmable logic device can be used.

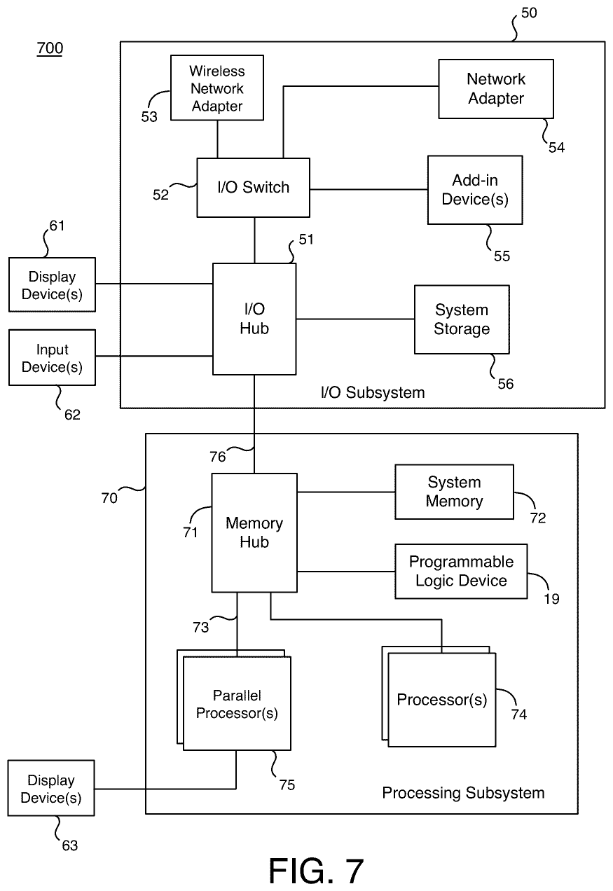

FIG. 7 is a block diagram illustrating a computing system 700 configured to implement one or more aspects of the embodiments described herein. The computing system 700 includes a processing subsystem 70 having one or more processor(s) 74, a system memory 72, and a programmable logic device 19 communicating via an interconnection path that can include a memory hub 71. The memory hub 71 can be a separate component within a chipset component or can be integrated within the one or more processor(s) 74. The memory hub 71 couples with an input/output (I/O) subsystem 50 via a communication link 76. The I/O subsystem 50 includes an input/output (I/O) hub 51 that can enable the computing system 700 to receive input from one or more input device(s) 62. Additionally, the I/O hub 51 can enable a display controller, which can be included in the one or more processor(s) 74, to provide outputs to one or more display device(s) 61. In one embodiment, the one or more display device(s) 61 coupled with the I/O hub 51 can include a local, internal, or embedded display device.

In one embodiment, the processing subsystem 70 includes one or more parallel processor(s) 75 coupled to memory hub 71 via a bus or other communication link 73. The communication link 73 can use one of any number of standards based communication link technologies or protocols, such as, but not limited to, PCI Express, or can be a vendor specific communications interface or communications fabric. In one embodiment, the one or more parallel processor(s) 75 form a computationally focused parallel or vector processing system that can include a large number of processing cores and/or processing clusters, such as a many integrated core (MIC) processor. In one embodiment, the one or more parallel processor(s) 75 form a graphics processing subsystem that can output pixels to one of the one or more display device(s) 61 coupled via the I/O Hub 51. The one or more parallel processor(s) 75 can also include a display controller and display interface (not shown) to enable a direct connection to one or more display device(s) 63.

Within the I/O subsystem 50, a system storage unit 56 can connect to the I/O hub 51 to provide a storage mechanism for the computing system 700. An I/O switch 52 can be used to provide an interface mechanism to enable connections between the I/O hub 51 and other components, such as a network adapter 54 and/or a wireless network adapter 53 that can be integrated into the platform, and various other devices that can be added via one or more add-in device(s) 55. The network adapter 54 can be an Ethernet adapter or another wired network adapter. The wireless network adapter 53 can include one or more of a Wi-Fi, Bluetooth, near field communication (NFC), or other network device that includes one or more wireless radios.

The computing system 700 can include other components not shown in FIG. 7, including other port connections, optical storage drives, video capture devices, and the like, that can also be connected to the I/O hub 51. Communication paths interconnecting the various components in FIG. 7 can be implemented using any suitable protocols, such as PCI (Peripheral Component Interconnect) based protocols (e.g., PCI-Express), or any other bus or point-to-point communication interfaces and/or protocol(s), such as the NV-Link high-speed interconnect, or interconnect protocols known in the art.

In one embodiment, the one or more parallel processor(s) 75 incorporate circuitry optimized for graphics and video processing, including, for example, video output circuitry, and constitutes a graphics processing unit (GPU). In another embodiment, the one or more parallel processor(s) 75 incorporate circuitry optimized for general purpose processing, while preserving the underlying computational architecture. In yet another embodiment, components of the computing system 700 can be integrated with one or more other system elements on a single integrated circuit. For example, the one or more parallel processor(s) 75, memory hub 71, processor(s) 74, and I/O hub 51 can be integrated into a system on chip (SoC) integrated circuit. Alternatively, the components of the computing system 700 can be integrated into a single package to form a system in package (SIP) configuration. In one embodiment, at least a portion of the components of the computing system 700 can be integrated into a multi-chip module (MCM), which can be interconnected with other multi-chip modules into a modular computing system.

The computing system 700 shown herein is illustrative. Other variations and modifications are also possible. The connection topology, including the number and arrangement of bridges, the number of processor(s) 74, and the number of parallel processor(s) 75, can be modified as desired. For instance, in some embodiments, system memory 72 is connected to the processor(s) 74 directly rather than through a bridge, while other devices communicate with system memory 72 via the memory hub 71 and the processor(s) 74. In other alternative topologies, the parallel processor(s) 75 are connected to the I/O hub 51 or directly to one of the one or more processor(s) 74, rather than to the memory hub 71. In other embodiments, the I/O hub 51 and memory hub 71 can be integrated into a single chip. Some embodiments can include two or more sets of processor(s) 74 attached via multiple sockets, which can couple with two or more instances of the parallel processor(s) 75.

Some of the particular components shown herein are optional and may not be included in all implementations of the computing system 700. For example, any number of add-in cards or peripherals can be supported, or some components can be eliminated. Furthermore, some architectures can use different terminology for components similar to those illustrated in FIG. 7. For example, the memory hub 71 can be referred to as a Northbridge in some architectures, while the I/O hub 51 can be referred to as a Southbridge.

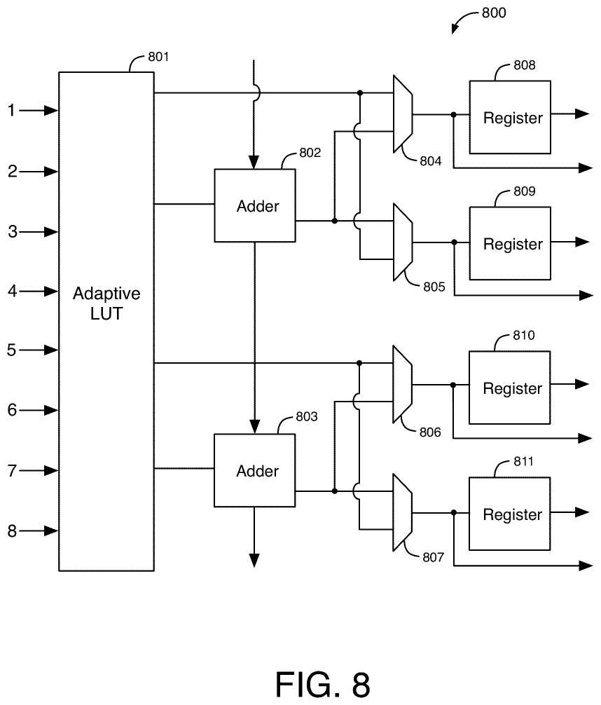

FIG. 8 is a diagram of an adaptive logic module (ALM) 800 that can implement one or more aspects of the embodiments disclosed herein. ALM 800 includes an 8-input fracturable adaptive lookup table (LUT) circuit 801, two dedicated adder circuits 802-803, four multiplexer circuits 804-807, and four dedicated register circuits 808-811. The adaptive LUT circuit 801 generates 4 output signals based on 8 input signals labeled 1-8 in FIG. 8. Two output signals of LUT circuit 801 are provided to data inputs of multiplexer circuits 804 and 806. Two additional output signals of LUT circuit 801 are provided to inputs of adder circuits 802-803. Adder circuits 802-803 each perform addition using an output signal of LUT circuit 801 and an output signal of another adder circuit to generate output signals (e.g., results of the addition). The output signals of adder circuits 802-803 are provided to data inputs of multiplexer circuits 804-805 and 806-807, respectively, as shown in FIG. 8. The signals selected by multiplexer circuits 804-807 are provided to and stored in register circuits 808-811, respectively, and also directly to outputs of the ALM 800. The signals stored in the register circuits 808-811 are additional outputs of ALM 800. ALM 800 can also include the LUTRAM circuit 100 of FIG. 1.

Additional examples are described below. Example 1 is a system comprising: a hard network-on-chip (NOC); and lookup table random access memory (LUTRAM) circuits usable as logic gates in a user design for an integrated circuit and reprogrammable in a user mode of the integrated circuit through the hard NOC.

In Example 2, the system of Example 1 may optionally include, wherein the LUTRAM circuits are reconfigurable during the user mode of the integrated circuit by providing a bit through the hard NOC for storage in one of the LUTRAM circuits.

In Example 3, the system of any one of Examples 1-2 may optionally include, wherein each of the LUTRAM circuits comprises a multiplexer circuit comprising a first data input coupled to the hard NOC and a second data input coupled to a reconfigurable routing channel in the integrated circuit, and wherein a bit at an output of each of the multiplexer circuits is provided for storage in one of the LUTRAM circuits.

In Example 4, the system of any one of Examples 1-3 further comprises: a programmable interconnect, wherein each of the LUTRAM circuits is configurable to store either a bit received from the hard NOC or a bit received from the programmable interconnect.

In Example 5, the system of any one of Examples 1-4 may optionally include, wherein each of the LUTRAM circuits comprises logic gates that receive a control signal, a pulse generator circuit coupled to the logic gates, and a decoder circuit, and wherein the pulse generator circuit generates a pulse in a signal to cause the decoder circuit to select a memory circuit to store a bit in response to the control signal.

In Example 6, the system of any one of Examples 1-5 may optionally include, wherein each of the LUTRAM circuits comprises a multiplexer that is coupled to receive select signals and data stored in memory circuits.

In Example 7, the system of any one of Examples 1-6 may optionally include, wherein the integrated circuit is a configurable integrated circuit, and wherein each of the LUTRAM circuits is configurable to store a bit in a memory circuit during the user mode without reconfiguring any other portion of the configurable integrated circuit.

In Example 8, the system of any one of Examples 1-7 may optionally include, wherein a bit is stored in a memory circuit in one of the LUTRAM circuits in a hybrid mode of the one of the LUTRAM circuits through a user data line that is coupled to the memory circuit, and wherein the one of the LUTRAM circuits further comprises logic gates that block access to the user data line in a lookup table mode of the one of the LUTRAM circuits during the user mode.

In Example 9, the system of any one of Examples 1-8 may optionally include, wherein configuration bits are provided to and stored in memory circuits in one of the LUTRAM circuits through configuration data lines during a configuration mode of the integrated circuit.

Example 10 is a method of on-the-fly reprogramming of logic gates in a field programmable gate array (FPGA) design without using configurable routing resources, the method comprising: implementing the logic gates using lookup table random access memories (LUTRAMs); and reprogramming the LUTRAMs using a hard network-on-chip (NOC).

In Example 11, the method of Example 10 may optionally include, wherein reprogramming the LUTRAMs using the hard (NOC) further comprises providing a bit through the hard NOC and a multiplexer circuit to a memory cell in one of the LUTRAMs.

In Example 12, the method of any one of Examples 10-11 may optionally include, wherein reprogramming the LUTRAMs using the hard (NOC) further comprises providing a bit through a configurable routing interconnect and a multiplexer circuit to a memory cell in one of the LUTRAMs.

In Example 13, the method of any one of Examples 10-12 may optionally include, wherein reprogramming the LUTRAMs using the hard (NOC) further comprises reconfiguring the LUTRAMs using bits to change constants or coefficients of a multiplier.

In Example 14, the method of any one of Examples 10-13 may optionally include, wherein reprogramming the LUTRAMs using the hard (NOC) further comprises adjusting weights for a neural network in a machine learning application by reconfiguring the LUTRAMs.

In Example 15, the method of any one of Examples 10-14 may optionally include, wherein reprogramming the LUTRAMs using the hard (NOC) further comprises changing fixed coefficients, weights, or kernels in an application on-the-fly without reconfiguring and recompiling the FPGA design that implements the application.

Example 16 is a logic block comprising: a lookup table circuit; and memory cells coupled to provide first bits stored in the memory cells to the lookup table circuit, wherein the lookup table circuit is configurable to implement logic gates in a circuit design for an integrated circuit comprising the logic block based on the first bits received from the memory cells, wherein one of the memory cells is coupled to receive and store a second bit during a user mode of the integrated circuit, and wherein the lookup table circuit is reconfigurable during the user mode of the integrated circuit based on the second bit received from the one of the memory cells.

In Example 17, the logic block of Example 16 may optionally include, wherein the one of the memory cells is coupled to receive the second bit during the user mode of the integrated circuit through a hard network-on-chip for storage in the one of the memory cells to reconfigure the lookup table circuit.

In Example 18, the logic block of any one of Examples 16-17 further comprises: a multiplexer circuit coupled to receive the second bit at a first data input coupled to a hard network-on-chip or at a second data input coupled to a reconfigurable routing interconnect, wherein a value at an output of the multiplexer circuit is provided for storage in the one of the memory cells.

In Example 19, the logic block of any one of Examples 16-18 may optionally include, wherein the logic block further comprises a pulse generator circuit and a decoder circuit, and wherein the pulse generator circuit generates a pulse in a first signal to cause the decoder circuit to select the one of the memory cells to store the second bit in response to a control signal during the user mode.

In Example 20, the logic block of any one of Examples 16-19 may optionally include, wherein the lookup table circuit comprises a multiplexer that receives select signals at select inputs and contents stored in the memory cells at data inputs.

The foregoing description of the exemplary embodiments has been presented for the purpose of illustration. The foregoing description is not intended to be exhaustive or to be limiting to the examples disclosed herein. The foregoing is merely illustrative of the principles of this disclosure and various modifications can be made by those skilled in the art. The foregoing embodiments may be implemented individually or in any combination.

What is claimed is:

1. A system comprising:
a hard network-on-chip (NOC); and
lookup table random access memory (LUTRAM) circuits usable as logic gates in a user design for an integrated circuit and reprogrammable in a user mode of the integrated circuit through the hard NOC.

2. The system of claim 1, wherein the LUTRAM circuits are reconfigurable during the user mode of the integrated circuit by providing a bit through the hard NOC for storage in one of the LUTRAM circuits.

3. The system of claim 1, wherein each of the LUTRAM circuits comprises a multiplexer circuit comprising a first data input coupled to the hard NOC and a second data input coupled to a reconfigurable routing channel in the integrated circuit, and wherein a bit at an output of each of the multiplexer circuits is provided for storage in one of the LUTRAM circuits.

4. The system of claim 1 further comprising:
a programmable interconnect, wherein each of the LUTRAM circuits is configurable to store either a bit received from the hard NOC or a bit received from the programmable interconnect.

5. The system of claim 1, wherein each of the LUTRAM circuits comprises logic gates that receive a control signal, a pulse generator circuit coupled to the logic gates, and a decoder circuit, and wherein the pulse generator circuit generates a pulse in a signal to cause the decoder circuit to select a memory circuit to store a bit in response to the control signal.

6. The system of claim 1, wherein each of the LUTRAM circuits comprises a multiplexer that is coupled to receive select signals and data stored in memory circuits.

7. The system of claim 1, wherein the integrated circuit is a configurable integrated circuit, and wherein each of the LUTRAM circuits is configurable to store a bit in a memory circuit during the user mode without reconfiguring any other portion of the configurable integrated circuit.

8. The system of claim 1, wherein a bit is stored in a memory circuit in one of the LUTRAM circuits in a hybrid mode of the one of the LUTRAM circuits through a user data line that is coupled to the memory circuit, and wherein the one of the LUTRAM circuits further comprises logic gates that block access to the user data line in a lookup table mode of the one of the LUTRAM circuits during the user mode.

9. The system of claim 1, wherein configuration bits are provided to and stored in memory circuits in one of the LUTRAM circuits through configuration data lines during a configuration mode of the integrated circuit.

10. A method of on-the-fly reprogramming of logic gates in a field programmable gate array (FPGA) design without using configurable routing resources, the method comprising:
implementing the logic gates using lookup table random access memories (LUTRAMs); and
reprogramming the LUTRAMs using a hard network-on-chip (NOC).

11. The method of claim 10, wherein reprogramming the LUTRAMs using the hard (NOC) further comprises providing a bit through the hard NOC and a multiplexer circuit to a memory cell in one of the LUTRAMs.

12. The method of claim 10, wherein reprogramming the LUTRAMs using the hard (NOC) further comprises providing a bit through a configurable routing interconnect and a multiplexer circuit to a memory cell in one of the LUTRAMs.

13. The method of claim 10, wherein reprogramming the LUTRAMs using the hard (NOC) further comprises reconfiguring the LUTRAMs using bits to change constants or coefficients of a multiplier.

14. The method of claim 10, wherein reprogramming the LUTRAMs using the hard (NOC) further comprises adjusting weights for a neural network in a machine learning application by reconfiguring the LUTRAMs.

15. The method of claim 10, wherein reprogramming the LUTRAMs using the hard (NOC) further comprises changing fixed coefficients, weights, or kernels in an application on-the-fly without reconfiguring and recompiling the FPGA design that implements the application.

16. A logic block comprising:
a lookup table circuit; and
memory cells coupled to provide first bits stored in the memory cells to the lookup table circuit, wherein the lookup table circuit is configurable to implement logic gates in a circuit design for an integrated circuit comprising the logic block based on the first bits received from the memory cells, wherein one of the memory cells is coupled to receive and store a second bit during a user mode of the integrated circuit, and wherein the lookup table circuit is reconfigurable during the user mode of the integrated circuit based on the second bit received from the one of the memory cells.

17. The logic block of claim 16, wherein the one of the memory cells is coupled to receive the second bit during the user mode of the integrated circuit through a hard network-on-chip for storage in the one of the memory cells to reconfigure the lookup table circuit.

18. The logic block of claim 16 further comprising:
a multiplexer circuit coupled to receive the second bit at a first data input coupled to a hard network-on-chip or at a second data input coupled to a reconfigurable routing interconnect, wherein a value at an output of the multiplexer circuit is provided for storage in the one of the memory cells.

19. The logic block of claim 16 further comprising:
a pulse generator circuit; and
a decoder circuit, wherein the pulse generator circuit generates a pulse in a first signal to cause the decoder circuit to select the one of the memory cells to store the second bit in response to a control signal during the user mode.

20. The logic block of claim 16, wherein the lookup table circuit comprises a multiplexer that receives select signals at select inputs and contents stored in the memory cells at data inputs.
